(19) United States
(12) Patent Application Publication
(10) Pub. No.: US 2015/0177289 A1
(43) Pub. Date: Jun. 25, 2015

(54) POWER DETECTOR CIRCUIT

(71) Applicants: Nazar Haider, Fremont, CA (US); Hendra Rustam, Santa Clara, CA (US); Guneet Singh, Santa Clara, CA (US)

(72) Inventors: Nazar Haider, Fremont, CA (US); Hendra Rustam, Santa Clara, CA (US); Guneet Singh, Santa Clara, CA (US)

(21) Appl. No.: 14/125,448

(22) PCT Filed: Jun. 28, 2013
(86) PCT No.: PCT/US2013/048774

§ 371 Date: Dec. 11, 2013

(51) Int. Cl. G01R 19/30; H03M 1/66; G06F 1/32; G01R 19/00

(52) U.S. Cl. CPC G01R 19/30; G01R 19/0084; H03M 1/66; G06F 1/3209

(57) ABSTRACT

The present disclosure describes a circuit for managing power and heat. The circuit includes a motherboard voltage regulator to supply a current to a loadline. The circuit includes a sense point coupled to the loadline, the circuit to measure a sensed voltage at the sense point. The circuit also includes a comparator to compare the sensed voltage to a reference voltage. An output of the comparator is used to indicate a level of current being provided by the motherboard voltage regulator.

### BACKGROUND

The number of cores has rapidly increased for each new generation of servers, thanks to a constantly growing need for improved server performance. However, the total power envelope for each generation of servers has not changed. Power management is used to control and reduce power usage so that the server delivers optimal performance and the power supply does not get overloaded.

### BRIEF DESCRIPTION OF THE FIGURES

The following detailed description may be better understood by referencing the accompanying drawings, which contain specific examples of numerous objects and features of the disclosed subject matter.

FIG. 1 is a block diagram of a system for power management and delivery in an electronic device.

FIG. 2 is a graph illustrating the relationship between voltage and current in a power detector circuit.

FIG. 3 is a graph illustrating sensed voltage levels in a power detector circuit for various server platform configurations.

FIG. 4 is a diagram of an embodiment of a power detector circuit.

FIG. 5 is a diagram of an embodiment of a power detector circuit.

FIG. 6 is a diagram of an embodiment of a power detector circuit.

FIG. 7 is a diagram of an embodiment of a power detector circuit.

FIG. 8 is a diagram of an embodiment of a power detector circuit.

FIG. 9 is a process flow diagram of a method for detecting maximum power usage.

### DETAILED DESCRIPTION

The present disclosure is related to thermal management and platform level power management and delivery in an electronic device. Thermal design power (TDP) represents the amount of power dissipated when a CPU is running at its nominal frequency while running the highest power real world application. Maximum application power (Pₐₚₚ) represents the maximum amount of power dissipated when the CPU is running non-virus applications, which can occur when the CPU is overclocked or in Turbo. Maximum power (Pₘₐₓ) is a power specification that refers to the absolute maximum power dissipated by the CPU during operation. A power virus is a malicious computer program that is coded to maximize CPU power dissipation (or thermal energy output), causing the electronic device to overheat over time. A power virus can cause the CPU to operate at Pₘₐₓ. Pₘₐₓ can be several times greater than TDP, and may be substantially greater than Pₐₚₚ. Pₘₐₓ is not sustainable by the server platform's power supply.

With each successive generation of server platform, the number of cores has increased, leading to a steep increase in Pₘₐₓ in relation to TDP. As Pₘₐₓ increases with each generation, so does the demand for larger power supplies and larger bulk caps on the server platform's motherboard to handle Pₘₐₓ conditions. This is a trend that is not sustainable due to the real estate and infrastructure required. By improving feedback time between the server platform's power supply and CPU, the Pₘₐₓ condition can be detected and remedied more quickly. As the CPU spends less time operating in Pₘₐₓ, the need for larger and more expensive bulk caps is reduced.

A power detector circuit in an electronic device can control the amount of power dissipated by a CPU in operation and reduce thermal output in order to prevent overheating. The power detector circuit can measure voltage at a sensing point, and determine if a certain power condition has been reached. A power condition can refer to a level of power dissipated by a central processing unit (CPU) during operation. If the power condition has been reached, the power detector circuit can send out an alert to reduce power production. By measuring voltage, the power detector circuit can provide fast feedback (within a few microseconds) that the power condition has been reached. The power detector circuit can also be adapted to be used for a number of different electronic device configurations. The power detector circuit can be used to detect when the electronic device is operating under unsustainable conditions, and take action to alleviate the unsustainable conditions.

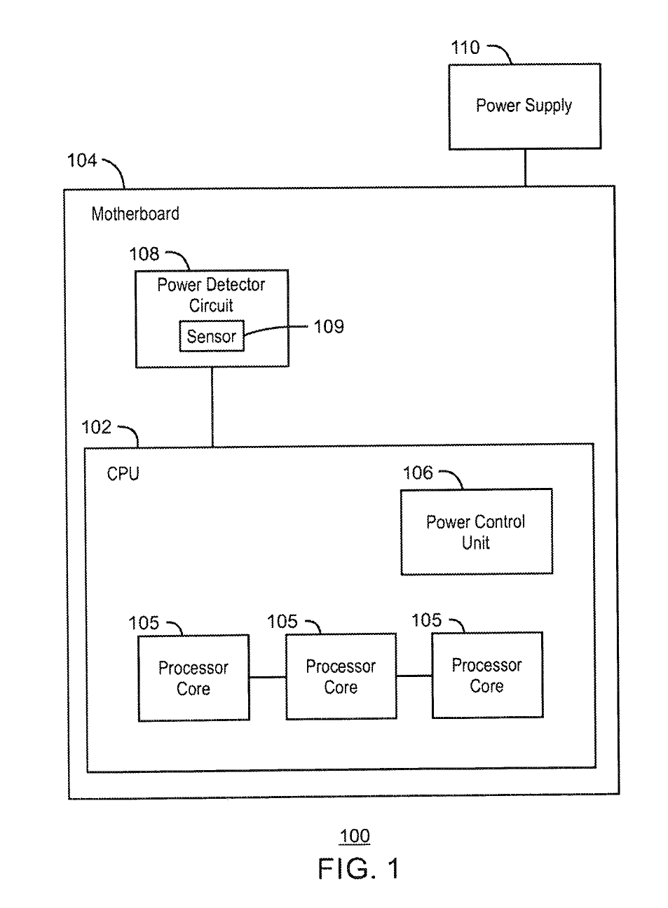

FIG. 1 is a block diagram of a system for power management and delivery in an electronic device. The system 100 can be used in an electronic device such as a server platform, a computer, a tablet, or a mobile phone. In some embodiments, the electronic device can utilize a multi-core processor.

The system 100 includes a central processing unit (CPU) 102 connected to a motherboard 104. The CPU 102 is used to run programs and applications, and may contain multiple processor cores 105. In some embodiments, the system 100 will utilize more than one CPU 102. A power control unit 106 is configured to deliver power to the one or more processor cores 102. The power control unit 106 can control the amount of power delivered to the one or more processor cores 102, and can throttle the one or more processor cores 102 in order to reduce power usage. The power control unit 106 can be coupled to or be contained in the CPU 102. A power supply 107 can deliver power to the motherboard.

A power detector circuit 108 can be coupled to the CPU 102 or the power control unit 106. The power detector circuit 108 is configured to measure how much power is being produced by the CPU 102 during operation. More specifically, a sensed voltage in the power detector circuit 108 can be measured at a sense point within the power detector circuit 108. In some embodiments, the sense point can be a sensor 109. If the sensed voltage is less than a pre-determined threshold, then the power detector circuit 108 can determine that a certain power condition has been detected. When the power condition has been detected, the power detector circuit 108 can send an alert to the power control unit 106, and command the power control unit 106 to throttle the one or more processor cores 102 to reduce power production.

The power condition can occur when a threshold of power produced is reached. In some embodiments, the threshold can be Pₘₐₓ, the maximum amount of power produced while a processor core 102 is running a power virus. In some embodiments, a user can set the threshold at a particular level, e.g. Pₐₚₚ.

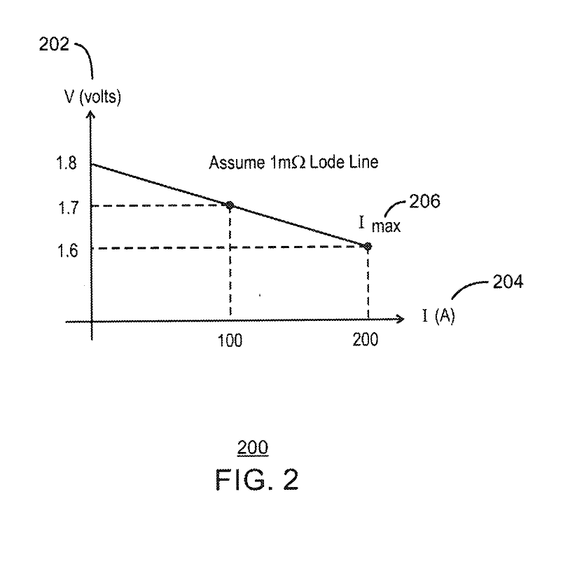

FIG. 2 is a graph illustrating the relationship between voltage and current in a power detector circuit. As is seen in the graph 200, the voltage 202 is proportional to the current 204. The current 204 can be supplied from a voltage regulator to a loadline in a circuit. The current 204 can represent the amount of power produced during CPU operation. Iₘₐₓ 206 represents the current at Pₘₐₓ, the maximum amount of power produced while a CPU is running a power virus.

In one example, the loadline of FIG. 2 has a resistance of 1 mU. A motherboard voltage regulator provides a nominal voltage of 1.8 V, which is the voltage of the loadline when no current is present. When the current is at Iₘₐₓ (200 A), the voltage in the loadline is 1.6 V.

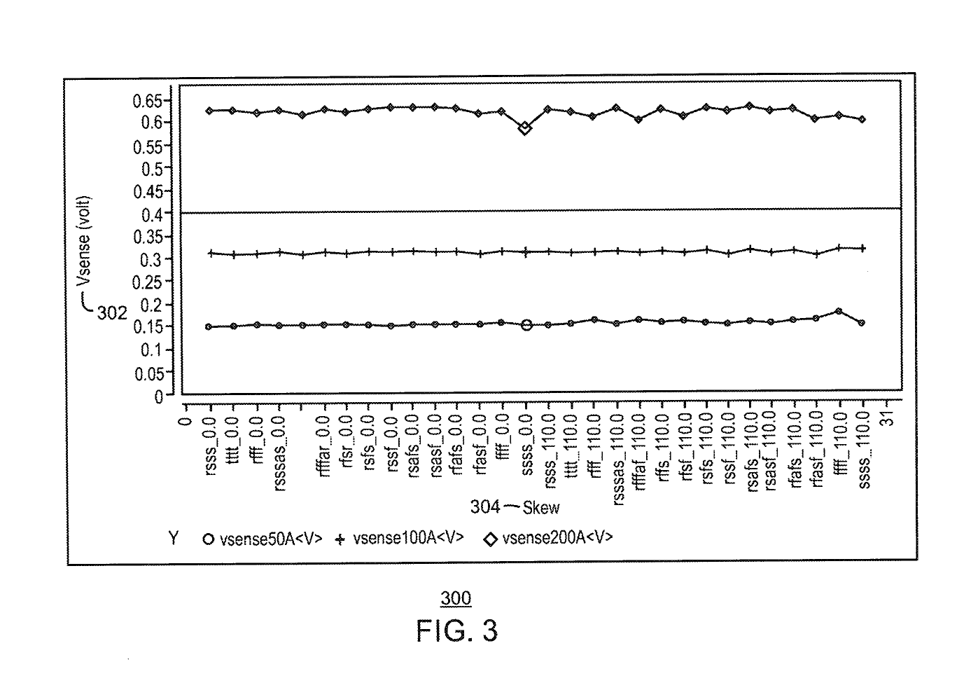

FIG. 3 is a graph illustrating sensed voltage levels in a power detector circuit for various server platform configurations. The graph 300 displays the voltage sensed 302 for platform configurations, also known as skews, at three different current levels using a power detecting circuit. Each skew 604 is represented by a series of letters that indicate characteristics of the server platform's components, and a number that represents operating temperature. Each component of the server platform may be realistic (indicated by “r”), typical (“t”), slow (“s”), or fast (“f”). For example, “typical” represents a CPU part that consists of transistors and interconnects which are deemed typical for the process technology that the CPU is manufactured with. The operating temperature may be between 0° C. and 110° C. For example, the skew “rsss_{—}0.0” indicates a realistic server platform with a slow P transistor, a slow N transistor, a slow processor, and an operating temperature of 0° C.

It is to be noted that the sensed voltage readings 302 at each current level is relatively consistent across the different skews 304. This indicates that the power detecting circuit 108 may be used adaptable for different configurations.

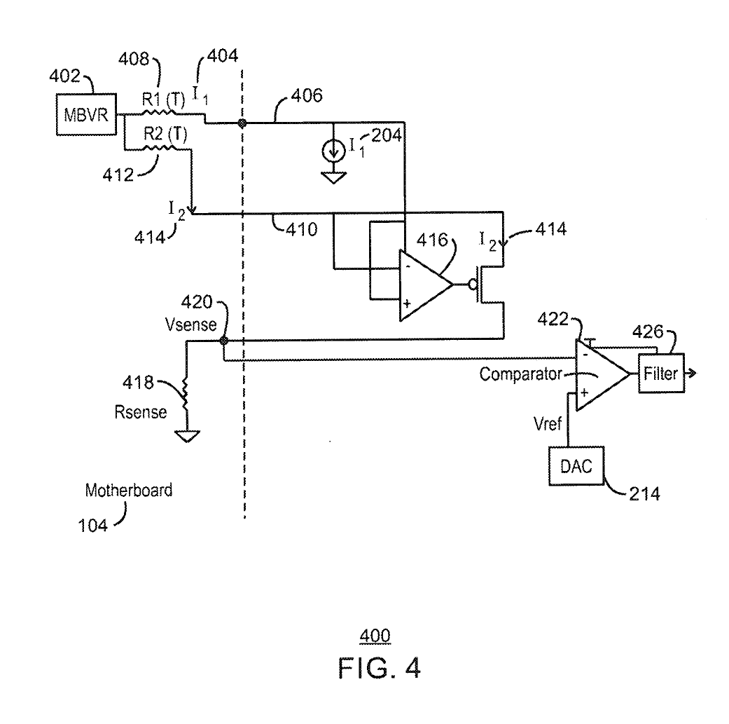

FIG. 4 is a diagram of an embodiment of a power detector circuit. The power detector circuit 400, which is an example of the power detector circuit 108 shown in FIG. 1, can monitor power production and notify a power control unit 106 if a certain power condition has been reached. The power detector circuit 400 is configured for current mode sensing. In current mode sensing, a motherboard voltage regulator (MBVR) 402 supplies currents to a pair of circuit lines in order to cancel out temperature-related variance in the resistance of the circuit lines.

The MBVR 402 coupled to a motherboard 104 supplies a first current (I₁) 404 to a loadline 406 with a first resistor (R₁(T)) 408. The loadline 406 can represent connection from the MBVR to a CPU 102 in which the first current 404 is provided. The resistance value of the first resistor 408 may vary depending on temperature. A second line 410 with a second resistor (R₂(T)) 412 can be coupled to the loadline 406, such that a second current (I₂) 414 travels along the second line 410. The resistance value of the second resistor 412 may also vary depending on temperature. The first resistor 408 and the second resistor 412 may be in close thermal proximity of one another, such that they both experience proportionally similar changes in resistance.

The loadline 406 and the second line 410 are coupled to an amplifier 416. The amplifier 416 can be used to force the voltage across the first resistor 408 and the voltage across the second resistor 412 to be equal. The loadline 406 can be connected to the positive input of the amplifier 416, and the second line 410 can be coupled to the negative input of the amplifier 416. The amplifier 416 can be a low offset amplifier.

The output of the amplifier 416 is coupled to a precision resistor (Rₛₑₙₛₑ) 418, which may be coupled to the motherboard 104. The sensed voltage (Vₛₑₙₛₑ) across the precision resistor 218 can be measured by the power detector circuit 200 at a sense point 420 nearby. The sense point 420 is connected to an input of a comparator 422. The other input is connected to a digital-to-analog converter (DAC) 424, which is configured to provide a reference voltage (V_{ref}) to the comparator 422. The reference voltage may be the voltage level in which maximum power (Pₘₐₓ) occurs. The reference voltage may also be a user-defined voltage level. The DAC 424 can be coupled to the motherboard 104 or the power control unit 106.

The comparator 422 can compare the sensed voltage to the reference voltage. A filter 426 coupled to the output of the comparator 422 can detect if the sensed voltage falls below the reference voltage for a sustained amount of time. If the sensed voltage does fall below the reference voltage for a sustained amount of time, the power detector circuit 400 can send an alert to the power control unit 106 that a power condition has been reached, and command the power control unit 106 to throttle or slow down operation in one or more processor cores 102.

From the measured value of the sensed voltage and the known values of the resistors, the value of the first current can ultimately be calculated. The sensed voltage at the precision resistor 418 is caused by the second current 414. Therefore, the value of the second current 418 can be determined by in the following equation:

Vₛₑₙₛₑ=I₂Rₛₑₙₛₑ

The amplifier 416 forces the voltage across the first resistor 408 and the voltage across the second resistor 412 to be equal. Thus, any change in resistance in the first resistor 408 due to temperature is effectively canceled out due to a proportionally equal change in resistance in the second resistor 412. Therefore, the value of the first current can be determined in the following equation:

I₁R₁=I₂R₂

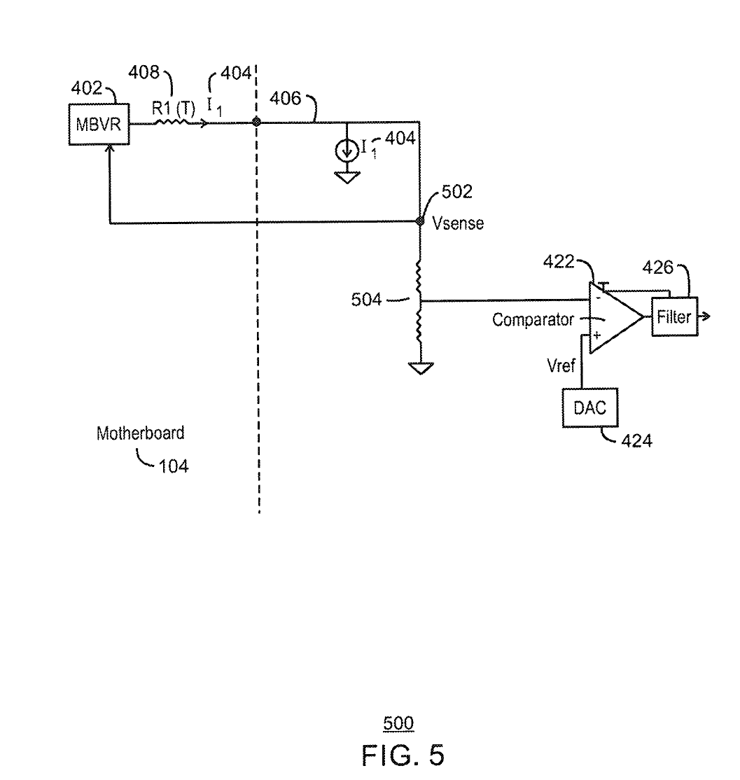

FIG. 5 is a diagram of an embodiment of a power detector circuit. The power detector circuit 500, which is an example of the power detector circuit 108 shown in FIG. 1, can be configured to power production and notify a power control unit if a certain power condition has been reached. The power detector circuit is configured for voltage mode sensing. In voltage mode sensing, a motherboard voltage regulator (MBVR) 402 is used to cancel out temperature-related variance in a circuit line.

The MBVR 402 coupled to a motherboard 104 supplies a first current (I₁) 404 to a loadline 406 with a first resistor (R₁(T)) 408. The loadline 406 can represent connection from the MBVR to a CPU 102 in which the first current 404 is provided. The resistance value of the first resistor 408 may vary depending on temperature. The loadline 406 may loop back to the MBVR 402, allowing the MBVR 402 to regulate and cancel any temperature-related changes in the resistance of the first resistor 408.

The sensed voltage (Vₛₑₙₛₑ) along the loadline 406 can be measured at a sense point 502. The sense point 502 is connected to an input of a comparator 422. The other input is connected to a digital-to-analog converter (DAC) 424, which is configured to provide a reference voltage (V_{ref}) to the comparator 422. The reference voltage may be the voltage level in which maximum power (Pₘₐₓ) occurs. The reference voltage may also be a user-defined voltage level. The DAC 424 can be coupled to the motherboard 104 or the power control unit 106.

The comparator 422 can compare the sensed voltage to the reference voltage. A filter 426 coupled to the output of the comparator 422 can detect if the sensed voltage falls below the reference voltage for a sustained amount of time. If the sensed voltage does fall below the reference voltage for a sustained amount of time, the power detector circuit 400 can send an alert to the power control unit 106 that a power condition has been reached, and command the power control unit 106 to throttle or slow down operation in one or more processor cores 102.

In some embodiments, the comparator 422 may not be able to accept a high voltage. Thus, the sensed voltage may be reduced using a voltage divider 504 at the sense point 502. The voltage divider 504 may be a resistive divider, a low-pass RC filter, an inductive divider, or a capacitive divider. Accordingly, the reference voltage can be scaled down with the voltage ratio of the voltage divider 504.

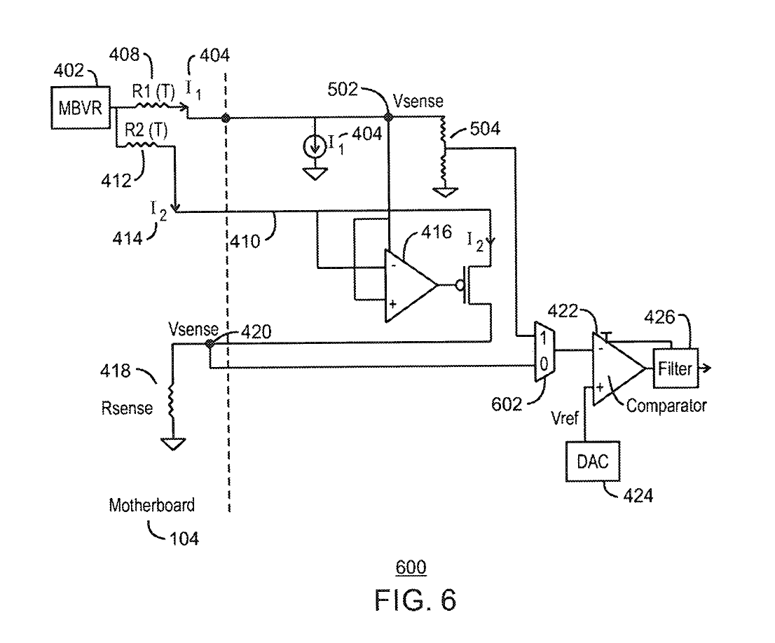

FIG. 6 is a diagram of an embodiment of a power detector circuit. The power detector circuit 600, which is an example of the power detector circuit 108 shown in FIG. 1, can be configured to power production and notify a power control unit if a certain power condition has been reached. The power detector circuit is configured to switch between current mode sensing and voltage mode sensing.

The power detector circuit 600 includes components shown in the circuits illustrated FIGS. 4 and 5, along with a switch 602 that allows the power detector circuit 600 to change between the circuit configured for current mode sensing (FIG. 4) and the circuit configured for voltage mode sensing (FIG. 5).

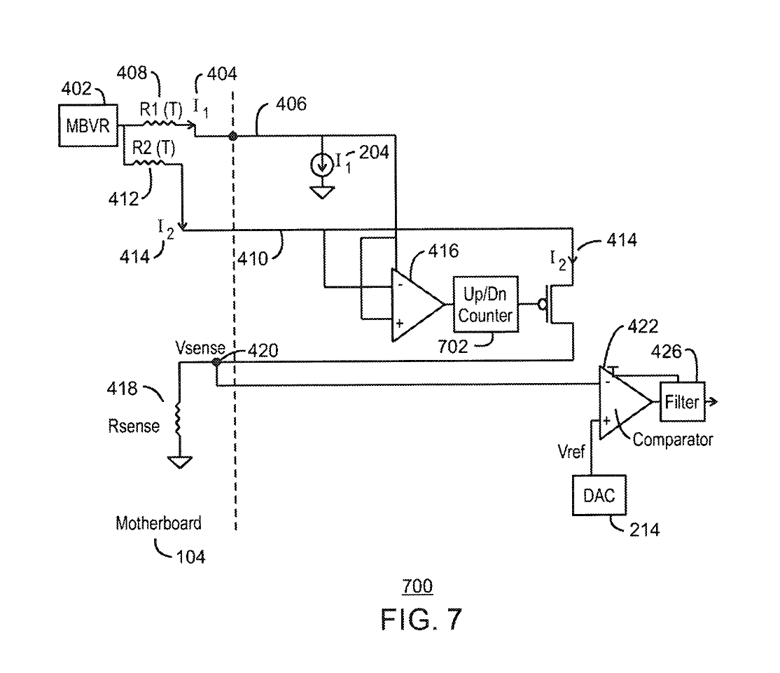

FIG. 7 is a diagram of an embodiment of a power detector circuit. The power detector circuit 700, which is an example of the power detector circuit 108 shown in FIG. 1, can monitor power production and notify a power control unit 106 if a certain power condition has been reached. The power detector circuit 700 is configured for current mode sensing. In current mode sensing, a motherboard voltage regulator (MBVR) 402 supplies currents to a pair of circuit lines in order to cancel out temperature-related variance in the resistance of the circuit lines.

The power detector circuit 700 includes components shown in the circuit illustrated in FIG. 4. The power detector circuit further includes an up/down counter 702 coupled to the output of the amplifier 416. The up/down counter 702 can compare the voltage from the loadline 406 (referred to herein as V₁) to the voltage from the second line 410 (referred to herein as V₂). If V₂ is greater than V₁, the up/down counter 702 can count down in response, and enable transistors to increase the second current I₂ 414 such that the value of V₂ is incrementally reduced to be equal to V₁. If V₂ is less than V₁, the up/down counter 702 can count up in response, and disable transistors to decrease the second current I₂ 414 such that the value of V₂ is incrementally increased to be equal to V₁.

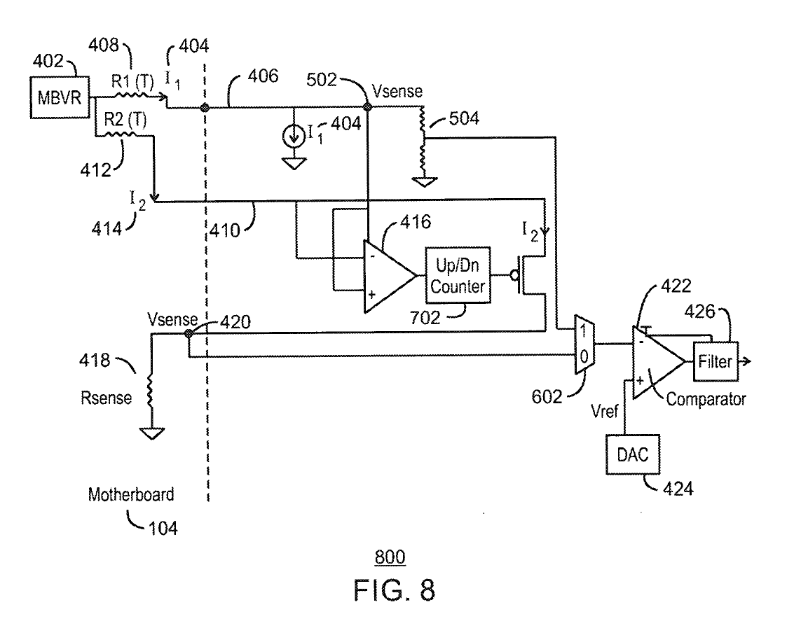

FIG. 8 is a diagram of an embodiment of a power detector circuit. The power detector circuit 800, which is an example of the power detector circuit 108 shown in FIG. 1, can monitor power production and notify a power control unit 106 if a certain power condition has been reached. The power detector circuit 800 is configured to switch between current mode sensing and voltage mode sensing.

The power detector circuit 800 includes components shown in the circuit illustrated in FIG. 6. The power detector circuit further includes an up/down counter 702 coupled to the output of the amplifier 416. The up/down counter 702 can compare the voltage from the loadline 406 (referred to herein as V₁) to the voltage from the second line 410 (referred to herein as V₂). If V₂ is greater than V₁, the up/down counter 702 can count down in response, and enable transistors to increase the second current I₂ 414 such that the value of V₂ is incrementally reduced to be equal to V₁. If V₂ is less than V₁, the up/down counter 702 can count up in response, and disable transistors to decrease the second current I₂ 414 such that the value of V₂ is incrementally increased to be equal to V₁.

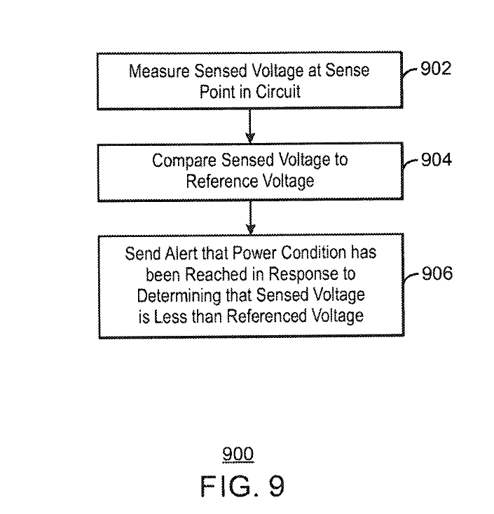

FIG. 9 is a process flow diagram of a method for detecting maximum power usage. The method 900 can be performed by a circuit in an electronic device. At block 902, the circuit determines a sensed voltage at a precision resistor. At block 904, the circuit compares the sensed voltage to a reference voltage. At block 906, the circuit sends an alert that a power condition has been reached in response to determining that the sensed voltage is less than the reference voltage.

Although some embodiments have been described in reference to particular implementations, other implementations are possible according to some embodiments. Additionally, the arrangement and order of circuit elements or other features illustrated in the drawings or described herein need not be arranged in the particular way illustrated and described. Many other arrangements are possible according to some embodiments.

In each system shown in a figure, the elements in some cases may each have a same reference number or a different reference number to suggest that the elements represented could be different or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Although flow diagrams and state diagrams may have been used herein to describe embodiments, the inventions are not limited to those diagrams or to corresponding descriptions herein. For example, flow need not move through each illustrated box or state or in exactly the same order as illustrated and described herein.

The inventions are not restricted to the particular details listed herein. Indeed, those skilled in the art having the benefit of this disclosure will appreciate that many other variations from the foregoing description and drawings may be made within the scope of the present inventions. Accordingly, it is the following claims including any amendments thereto that define the scope of the inventions.

What is claimed is:

1. A circuit, comprising:
a motherboard voltage regulator to supply a current to a loadline;
a sense point coupled to the loadline, the circuit to measure a sensed voltage at the sense point; and
a comparator to compare the sensed voltage to a reference voltage;
wherein an output of the comparator is used to indicate a level of current being provided by the motherboard voltage regulator.

2. The circuit of claim 1, comprising:
a second line coupled to the motherboard voltage regulator;
a precision resistor at the sense point; and
an amplifier to cancel out temperature-related variation in the resistance of the loadline, wherein the loadline and the second line are each coupled to an input of the amplifier, and the precision resistor is coupled to the output of the amplifier.

3. The circuit of claim 2, comprising a switch to change between voltage mode sensing and current mode sensing.

4. The circuit of claim 1, comprising a voltage divider at the sense point.

5. The circuit of claim 1, comprising a digital-to-analog converter (DAC) coupled to an input of the comparator, the DAC to provide a value of the reference voltage.

6. The circuit of claim 1, comprising a filter coupled to the output of the comparator, the filter to detect when the sensed voltage is less than the reference voltage for a sustained period of time.

7. The circuit of claim 1, wherein the loadline provides power from the motherboard voltage regulator to a plurality of processor cores.

8. The circuit of claim 7, wherein the sensed voltage dropping below the reference voltage indicates that a power virus is executing on one or more of the plurality of processor cores.

9. The circuit of claim 7, wherein if the sensed voltage drops below the reference voltage, a power control circuit throttles the plurality of processor cores.

10. The circuit of claim 1, wherein the sense point is a sensor.

11. A method, comprising:
measuring a sensed voltage at a sense point in a circuit, the sensed voltage corresponding to a voltage source motherboard voltage regulator;
comparing the sensed voltage to a reference voltage;
sending an alert that a power condition has been reached in response to determining that the sensed voltage is less than the reference voltage.

12. The method of claim 11, comprising calculating a current from the sensed voltage.

13. The method of claim 11, comprising throttling a processor core coupled to the motherboard voltage regulator if the sensed voltage is less than the reference voltage.

14. The method of claim 11, comprising canceling out temperature-related variance in the resistance of a loadline in the circuit.

15. The method of claim 11, wherein the alert indicates that a power virus is operating processor core coupled to the motherboard voltage regulator.

16. An electronic device comprising:
a motherboard;
a processor core coupled to the motherboard;
a circuit coupled to the motherboard and the processor core, the circuit comprising:
a motherboard voltage regulator to supply a current to the processor core through a loadline;
a sense point coupled to the loadline, the circuit to measure a sensed voltage at the sense point; and
a comparator to compare the sensed voltage to a reference voltage; and
a power control unit to throttle the processor core if the sensed voltage is below the reference voltage.

17. The electronic device of claim 16, the circuit comprising:
a second line coupled to the motherboard voltage regulator;
a precision resistor at the sense point; and
an amplifier to cancel out temperature-related variation in the resistance of the loadline, wherein the loadline and the second line are each coupled to an input of the amplifier, and the precision resistor is coupled to the output of the amplifier.

18. The electronic device of claim 17, the circuit comprising a switch to change between voltage mode sensing and current mode sensing.

19. The electronic device of claim 16, the circuit comprising a voltage divider at the sense point.

20. The electronic device of claim 16, the circuit comprising a digital-to-analog converter (DAC) coupled to an input of the comparator, the DAC to provide a value of the reference voltage.

21. The electronic device of claim 16, the circuit comprising a filter coupled to the output of the comparator, the filter to detect when the sensed voltage is less than the reference voltage for a sustained period of time.

22. The electronic device of claim 16, wherein the sense point is a sensor.
